(19) United States
(12) Patent Application Publication
(10) Pub. No.: US 2009/0189224 A1
(43) Pub. Date: Jul. 30, 2009

(54) SEMICONDUCTOR DEVICE AND FABRICATION PROCESS THEREOF

(75) Inventor: Koichi Matsumoto, Kanagawa (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(73) Assignee: Sony Corporation, Tokyo (JP)

(21) Appl. No.: 12/341,364

(22) Filed: Dec. 22, 2008

(30) Foreign Application Priority Data
Jan. 29, 2008 (JP) 2008-017119

(51) Int. Cl. H01L 27/092; H01L 21/8238

(52) U.S. Cl. 257/369; 438/275; 257/E27.062; 257/E21.632

(57) ABSTRACT

A semiconductor device includes: an insulated gate field effect transistor of a first conductivity type as a first transistor, the first transistor having a gate insulating film and a gate electrode; and an insulated gate field effect transistor of a second conductivity type opposite to the first conductivity type as a second transistor, the second transistor having a gate insulating film and a gate electrode.

### CROSS REFERENCES TO RELATED APPLICATIONS

The present invention contains subject matter related to Japanese Patent Application JP 2008-017119 filed in the Japan Patent Office on Jan. 29, 2008, the entire contents of which being incorporated herein by reference.

### BACKGROUND OF THE INVENTION

1. Field of the Invention

This invention relates to a semiconductor device, and also to its fabrication process.

2. Description of the Related Art

In existing CMOS (Complementary metal-oxide semiconductor), so-called high dielectric constant (high-k) films having dielectric constants of higher values than silicon oxide films are finding utility. Their use has already started in low leakage current products which are easier to introduce technologies (see, for example, “CMOS Logic Process Technology of 55-nanometer Node Developed at Practical Level for the First Time in the World (in Japanese)” [on line], Dec. 5, 2005, NEC Electronics, [Retrieved: Aug. 27, 2007], Internet <URL: {HYPERLINK “http://www.necel.com/news/ja/archive/0512/0501.html,” http:www.necel.com/news/ja/archive/0512/0501.html}>; and “Beginning of Acceptance of Orders for Cell Base IC of 55-nanometer Node Significantly Reduced in Power Consumption (in Japanese)” [on line], Jan. 17, 2007, NEC Electronics, [Retrieved: Aug. 27, 2007], Internet<{HYPERLINK “http://www.necel.com/news/ja/archive/0701/1801.html,” http:www.necel.com/news/ja/archive/0701/1801.html}>. Further, it has been reported to control a work function by using HfSiON in a gate insulating film (see, for example, H. Nakamura, et al., “55 nm CMOS Technology for Low Standby Power/Generic Applications Deploying the Combination of Gate Work Function Control by HfSiON and Stress-induced Mobility Enhancement,” 2006 Symp. of VLSI Tech.)

Nonetheless, the amount of Hf demanded to change a work function by an appropriate quantity (0.1 V to 0.3 V) is very little, for example, 1E13/cm² to 5E14/cm², so that as illustrated in FIG. 7, hafnium (Hf) treatment has been applied to provide hafnium (Hf) 122 on a gate insulating film 121 on the side of a existing gate electrode 123 (see, for example, Japanese Patent Laid-Open Nos. 2006-93670 and 2006-332179). In the above-described construction, the gate electrode 123 has been doped with a P-type impurity when it is a P-type FET (hereinafter called “PFET”), while the gate electrode 123 has been doped with an N-type impurity when it is an N-type FET (hereinafter called “NFET”).

No elucidation has been made yet as to the mechanism that changes the work function of a gate electrode by introducing a meal impurity such as hafnium (Hf) onto a gate insulating film. However, attempts have been made to explain the mechanism based on so-called Fermi level pinning (see, for example, C. Hobbs, et al., “Fermi Level Pinning at the PolySi/Metal Oxide Interface,” 2003 Symp. Of VLSI Tech., hereinafter referred to as Non Patent Document 4), dipole polarization caused by oxygen deficiency in a hafnium oxide film (see, for example, K. Shiraishi, et al., “Physics in Fermi Level Pinning at the PolySi/Hf-based High-k Oxide Interface,” 2004 Symp. Of VLSI Tech. p. 108), or the like. Such a change has been reported not only with hafnium (Hf) but also with aluminum (Al) (see, for example, Non Patent Document 4), and a wide variety of metal impurities have been proposed to control the threshold voltage of MOSFET.

Hafnium (Hf) is introduced because it makes it possible to achieve at a low impurity density a high threshold voltage which can in turn attain low leakage. Accordingly, a mobility reduction due to ionized impurity scattering can be inhibited to achieve electric field relaxation, whereby GIDL (gate induced drain leakage) can be reduced.

Disclosed as technologies for preventing the occurrence of Fermi level pinning in the gate electrode of PFET include the technology that combines platinum (Pt) rich silicide reduced in silicon (Si) content with boron (B) doping (see, for example, JP-A-2006-80133) and the technology that reduces a variation of the threshold value of the high dielectric constant (high-k) film of PFET by forming the high-k film thin (see, for example, Japanese patent Laid-Open No. 2006-327902).

### SUMMARY OF THE INVENTION

A problem to be solved is that, although the threshold value control making use of a metal impurity such as hafnium (Hf) can be applied to the existing CMOS fabrication technologies, the existing CMOS fabrication technologies use a boron(B)-containing P+-type polysilicon electrode in PFET and the troublesome gate depletion, which is a problem of the existing CMOS fabrication technologies, is inherited as it is.

It is desirable to control an effective work function while reducing gate depletion by contriving gate insulating films and gate electrodes.

In one embodiment of the present invention, there is thus provided a semiconductor device including: an insulated gate field effect transistor of a first conductivity type as a first transistor, the first transistor having a gate insulating film and a gate electrode, and an insulated gate field effect transistor of a second conductivity type opposite to the first conductivity type as a second transistor, the second transistor having a gate insulating film and a gate electrode. The gate insulating film of the first transistor and the gate insulating film of the second transistor are provided on sides of the gate electrodes with a metal impurity, respectively; and wherein the gate electrode of the first transistor includes polysilicon of the second conductivity type, or the gate electrode of the second transistor includes polysilicon of the first conductivity type, or the gate electrode of the first transistor includes polysilicon of the second conductivity type and the gate electrode of the second transistor includes polysilicon of the first conductivity type.

The semiconductor device according to the first embodiment of the present invention has the gate electrode formed of the polysilicon of the second conductivity, which is opposite to the first conductivity, in the gate insulated field effect transistor of the first conductivity type and the gate electrode formed of the polysilicon of the first conductivity in the gate insulated field effect transistor of the second conductivity type. Therefore, no gate depletion layer is formed, and a higher gate capacitance can be obtained. The term “higher gate capacitance” as used herein does not mean to increase the parasitic capacitance by increasing the gate capacitance beyond necessity. It means to obtain a gate capacitance which should be inherently available from miniaturization if no impairment took place due to gate depletion. Further, owing to the existence of the metal impurity on the gate electrode sides of the gate insulating films, the effective work function can be changed, for example, by 0.1 V to 0.3 V or so. In addition, a high threshold voltage can be achieved, and therefore, a mobility reduction due to ionized impurity scattering can be inhibited to achieve electric field relaxation, whereby GIDL (gate induced drain leakage) can be reduced.

In a second embodiment of the present invention, there is also provided a process for the fabrication of a semiconductor device, the process including formation of a P-type gate insulated field effect transistor as a first transistor and an N-type gate insulated field effect transistor as a second transistor, including the following steps of: forming a gate-insulating film on a semiconductor substrate; and depositing a metal impurity on the gate-insulating film. The process further including the steps of: forming gate electrodes for the first transistor and second transistor, respectively, on the gate insulating film with the metal impurity deposited thereon; forming source and drain regions in the semiconductor substrates at locations on opposite sides of the respective gate electrodes; and conducting at least one of introduction of an N-type impurity into the gate electrode for the first transistor and introduction of a P-type impurity into the gate electrode for the second transistor.

The process according to the second embodiment of the present invention for the fabrication of the semiconductor device introduces the N-type impurity into the gate electrode for the P-type insulated gate field effect transistor as the first transistor and the P-type impurity into the gate electrode for the N-type insulated gate field effect transistor as the second transistor. Therefore, no gate depletion layer is formed, and a higher gate capacitance can be obtained. Further, owing to the existence of the metal impurity on the gate electrode sides of the gate insulating films, the effective work function can be changed, for example, by 0.1 V to 0.3 V or so. In addition, a high threshold voltage can be achieved, and therefore, a mobility reduction due to ionized impurity scattering can be inhibited to achieve electric field relaxation, whereby GIDL (gate induced drain leakage) can be reduced.

The semiconductor device according to the first embodiment of the present invention can control the effective work function while inhibiting gate depletion, and therefore, has advantages that leakage can be reduced and the mobility can be improved.

The process according to the second embodiment of the present invention for the fabrication of the semiconductor device makes it possible to form a construction that can control the effective work function while inhibiting gate depletion, and therefore, has advantages that the semiconductor device can be reduced in leakage and can be improved in mobility.

### BRIEF DESCRIPTION OF THE DRAWINGS

FIG. 1 is a schematic cross-sectional construction diagram schematically illustrating one embodiment of the semiconductor device according to the first embodiment of the present invention.

FIG. 2 is a cross-sectional fabrication step diagram depicting one embodiment of the process according to the second embodiment of the present invention for the fabrication of a semiconductor device.

FIG. 3 is another cross-sectional fabrication step diagram depicting the one embodiment of the process according to the second embodiment of the present invention for the fabrication of the semiconductor device.

FIG. 4 is a further cross-sectional fabrication step diagram depicting the one embodiment of the process according to the second embodiment of the present invention for the fabrication of the semiconductor device.

FIG. 5 is a still further cross-sectional fabrication step diagram depicting the one embodiment of the process according to the second embodiment of the present invention for the fabrication of the semiconductor device.

FIG. 6 is a yet further cross-sectional fabrication step diagram depicting the one embodiment of the process according to the second embodiment of the present invention for the fabrication of the semiconductor device.

FIG. 7 is a schematic cross-sectional construction diagram schematically illustrating gate electrode portions in a existing semiconductor device.

### DETAILED DESCRIPTION OF THE PREFERRED EMBODIMENT

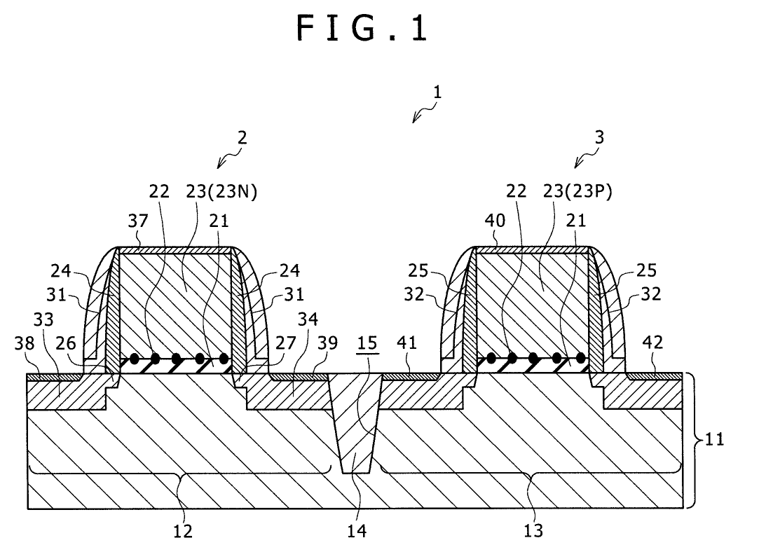

One embodiment of the semiconductor device according to the present invention will be described with reference to FIG. 1.

As shown in FIG. 1, an element-isolating region 14 is formed in a semiconductor substrate 11 to isolate element-forming regions 12, 13 from each other. These element-forming regions 12, 13 are to be used as active regions to form elements. This element-isolating region 14 has been formed, for example, by burying silicon oxide in an element-isolating trench (trench region) 15 formed in the semiconductor substrate 11. This element-isolating trench 15 is formed in the semiconductor substrate 11, for example, to a depth of 350 nm to 400 nm.

On the semiconductor substrate 11, the element-isolating region 14 has been planarized.

As described above, the element-forming regions 12, 13 are formed as the active regions isolated from each other by the element-isolating region 14.

A description will hereinafter be made of a semiconductor device 1 having a field effect transistor of a first conductivity type (for example, P-type) (hereinafter called “PFET 2”) formed at the element-forming region 12 and a field effect transistor of a second conductivity type opposite to the first conductivity type (for example, N-type) (hereinafter called “NFET 3”) formed at the element-forming region 13.

On the surfaces of the element-forming regions 12, 13, gate-insulating films 21 are formed, respectively. These gate-insulating films 21 are formed, for example, of silicon oxide films.

On these gate-insulating films 21, a meal impurity 22 exists. As the metal impurity 22, any of hafnium, aluminum, zirconium, lanthanum, praseodymium, yttrium, titanium, tantalum, and tungsten can be used, for example.

The metal impurity 22 may be one formed directly on the gate-insulating films 21, for example, by using a film-forming process such as an organic metal chemical vapor deposition (MOCVD) process, an atomic layer deposition (ALD) process or a physical vapor deposition (PVD) process. As an alternative, the metal impurity 22 may also be one introduced by ion implantation subsequent to the formation of the gate electrodes. When the ALD process is used, for example, the metal impurity 22 is formed of hafnium atoms or aluminum atoms deposited as several layers of atoms on the gate-insulating films 21.

On the gate-insulting films 21 with the metal impurity 22 existing on the surfaces thereof, gate electrodes 23 (23N, 23P) are formed. In these gate electrodes 23 (23N, 23P), a P-type impurity (for example, boron (B)) may be used for the gate electrode 23N of NFET or an N-type impurity (P) may be used for the gate electrode 23N of PFET, or the P-type impurity may be used for the gate electrode 23N of NFET and the N-type impurity (P) may be used for the gate electrode 23N of PFET. As conditions for the introduction of these impurities, they should be introduced such that they do not reach the corresponding gate-insulating films 21.

On side walls of the gate electrode 23N, offset spacers 24 are formed. On side walls of the gate electrode 23P, offset spacers 25 are also formed. These offset spacers 24, 25 are formed, for example, of silicon nitride (Si₃N₄) films of about 5 nm to 15 nm thickness.

P-type LLD (Lightly Doped Drain) regions 26, 27 are formed in the element-forming region 12 of PFET at locations below the respective offset spacers 24 on the opposite sides of the gate electrode 23N.

N-type LLD (Lightly Doped Drain) regions 28, 29 are formed in the element-forming region 13 of NFET at locations below the respective offset spacers 25 on the opposite sides of the gate electrode 23P.

To inhibit the short channel effect, a so-called “halo” region (not shown) may be formed concurrently with the formation of each LDD.

On the side walls of the gate electrode 23N, side walls 31 are formed via the offset spacers 24. On the side walls of the gate electrode 23P, side walls 32 are formed via the offset spacers 25. These side walls 31, 32 are formed, for example, of silicon nitride (Si₃N₄) films of about 50 nm to 70 nm thickness.

In the element-forming region 12, a P-type source-drain region 33 is formed via the P-type LDD region 26 on the one side of the gate electrode 23N. In the element-forming region 12, a P-type source-drain region 34 is formed via the P-type LDD region 27 on the other side of the gate electrode 23N.

In the element-forming region 13, an N-type source-drain region 35 is formed via the N-type LDD region 28 on the one side of the gate electrode 23P. In the element-forming region 13, an N-type source-drain region 36 is formed via the N-type LDD region 29 on the other side of the gate electrode 23P.

Low-resistance silicide layers 37, 38, 39, 40, 41, 42 are formed on the gate electrode 23N, the source-drain regions 33, 35, the gate electrode 23P and the source-drain regions 35, 36, respectively. These silicide layers 37 to 42 are formed, for example, with cobalt silicide (CoSi₂) or nickel silicide (NiSi).

In the above-described construction, any unnecessarily raised threshold voltage can be adjusted, for example, lowered by conducting counter doping which makes use of an impurity of opposite polarity.

As an alternative, the threshold voltage Vth can also be adjusted by an existing technology, specifically by introducing nitrogen (N) or fluorine (F) (see, for example, Y. Nishida, et al., “Performance Enhancement in 45-nm Ni Fully-Silicided Gate/High-k CMIS using Substrate Ion Implantation,” 2007 Symp. of VLSI Tech.) For example, fluorine is introduced into a channel region of the first transistor 2 as PFET. Further, nitrogen is introduced into a channel region of the second transistor 3 as NFET. In the above-described construction, the amounts of the impurities desired to lower the Vth can be more easily decreased in a technology which uses, as gate-insulating films, such high dielectric constant (high-k) films that the effective work functions of the gate electrodes are apart from the band edges.

In the semiconductor device 1 of the above-described construction, the first transistor 2 as PFET has the gate electrode 23N formed of N-type polysilicon, and the second transistor 3 as NFET has the gate electrode formed of P-type polysilicon. Therefore, no gate depletion layer is formed, and a higher gate capacitance can be obtained. The term “higher gate capacitance” as used herein does not mean to increase the parasitic capacitance by increasing the gate capacitance beyond necessity. It means to obtain a gate capacitance which should be inherently available from miniaturization if no impairment took place due to gate depletion.

Further, owing to the existence of the metal impurity such as hafnium or aluminum on the sides of the gate electrodes 23 in the gate insulating films 21, the effective work function can be changed, for example, by 0.1 V to 0.3 V or so.

In addition, a high threshold voltage can be achieved, and therefore, a mobility reduction due to ionized impurity scattering can be inhibited to achieve electric field relaxation, whereby GIDL (gate induced drain leakage) can be reduced.

It is, therefore, possible to control the effective work function while inhibiting gate depletion. Accordingly, the embodiment of the present invention has the advantages that the leakage can be reduced and the mobility can be improved.

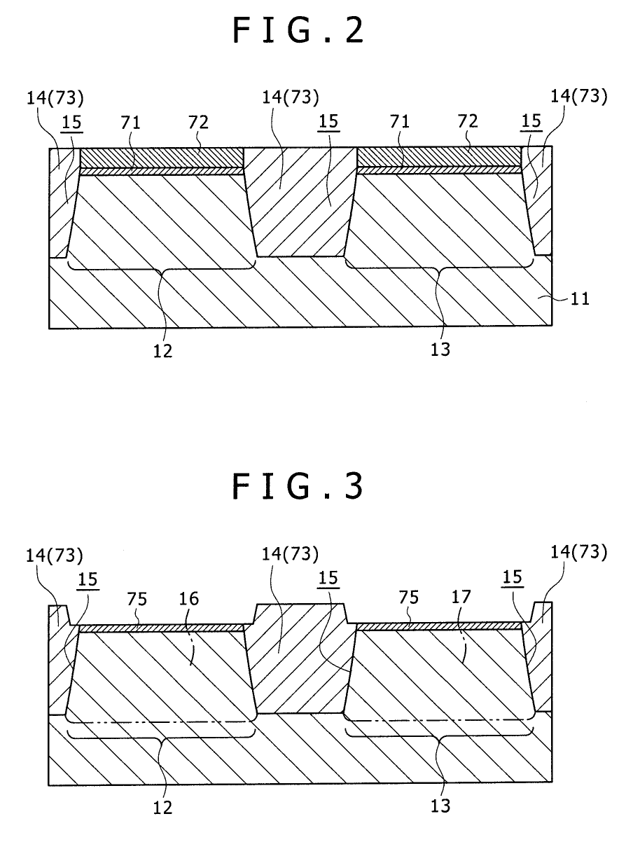

One embodiment of the process according to the second mode of the present invention for the fabrication of a semiconductor device will next be described with reference to FIGS. 2 through 6.

As shown in FIG. 2, the element-isolating region 14 is formed in the semiconductor substrate 11 to isolate the element-forming regions 12, 13 which are to be used as active regions. For the formation of the element-isolating region 14, an existing element isolation technology can be used. For example, a silicon substrate is used as the semiconductor substrate 11. After a silicon oxide film is formed as an oxide film 71 over the semiconductor substrate 11, a silicon nitride film is formed as a hard mask layer 72.

Resist patterns are formed on the element-forming regions 12, 13, and using these resist patterns as etching masks, the hard mask layer 72, oxide film 71 and semiconductor substrate 11 are sequentially etched to form the element-isolating trench (trench region) 15.

At this time, the semiconductor substrate 11 is etched, for example, to a depth of 350 nm to 400 nm. The regions of the semiconductor substrate 11, the regions being covered with the hard mask layers 72, are to be used as active regions, and the element-isolating trench 15 is to be used as a region where the element-isolating region 14 is to be formed.

Subsequently, the element-isolating trench 15 is buried with silicon oxide 73. A dense film of good step coverage can be formed, for example, by conducting the burying of the silicon oxide 73 in accordance with high-density plasma CVD.

By chemical mechanical polish (CMP), any surplus silicon oxide 73 on the semiconductor substrate 11 is polished off to perform planarization. In the regions where the hard mask layers 72 are formed, the polishing is performed to such extent that the silicon oxide 73 on the hard mask layers 72 are removed. FIG. 2 illustrates conditions after this polishing.

As depicted in FIG. 3, the hard mask layers 72 (see FIG. 2) are then removed. The removal of the hard mask films 72 can be conducted, for example, by wet etching with hot phosphoric acid, because the hard mask layers are formed of silicon nitride.

As a result, the element-isolating region 14 is formed with the element-isolating trench 15 being buried with the silicon oxide 73, and the element-forming regions 12, 13 as the active regions are isolated from each other by the element-isolating region 14.

By a washing step, the oxide films 71 (see FIG. 2) are removed.

Sacrificial oxide films 75 are subsequently formed on the surfaces of the element-forming regions 12, 13. These sacrificial oxide films 75 are formed, for example, of silicon oxide films of 10 nm thickness.

Next, an N-well region 16 is formed in the element-forming region 12 where PFET is to be formed. Ion implantation is performed to form a buried layer (not shown) for the prevention of a punch-through of FET, and further ion implantation is performed to adjust the Vth. As a result, a channel region (not shown) for PFET is formed in an upper part of the N-well region 16. In the ion implantation for the adjustment of the Vth, fluorine can be introduced, for example.

Further, a P-well region 17 is formed in the element-forming region 13 where NFET is to be formed. Ion implantation is performed to form a buried layer (not shown) for the prevention of a punch-through of FET, and further ion implantation is performed to adjust the Vth. As a result, a channel region (not shown) for NFET is formed in an upper part of the P-well region 17. In the ion implantation for the adjustment of the Vth, nitrogen can be introduced, for example.

Subsequently, the sacrificial oxide films 75 are removed. The removal of these sacrificial oxide films 75 can be conducted, for example, by wet etching with a fluorinated acid solution. FIG. 3 illustrates conditions before the removal of the sacrificial oxide films 75.

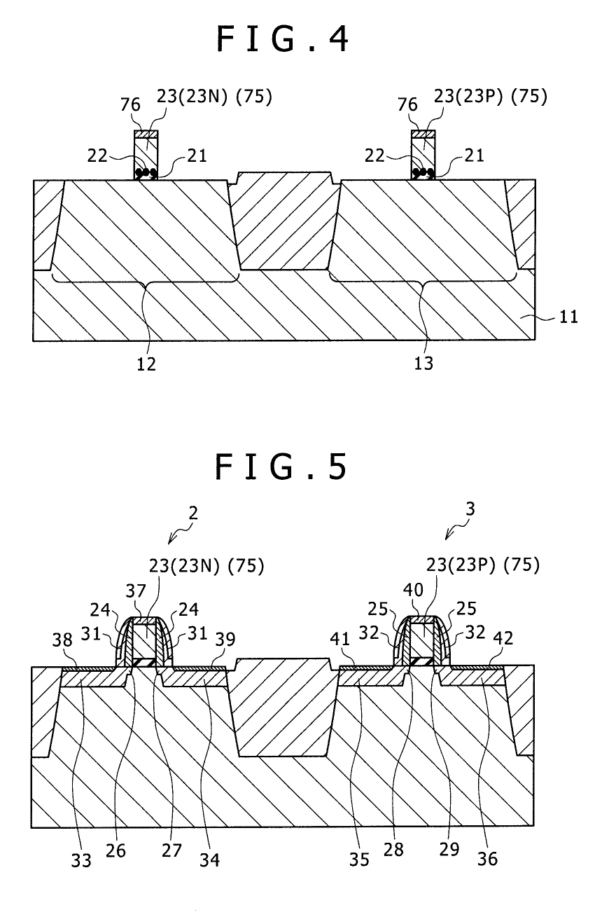

Reference is next had to FIG. 4. The gate-insulating films 21 are formed on the surfaces of the element-forming areas 12, 13 of the semiconductor substrate 11. These gate-insulating films 21 can be formed, for example, by causing silicon oxide films to grow to a thickness of 1.5 nm to 2.0 nm or so in accordance with dry oxidation (in an oxidizing atmosphere of 700° C. O₂). As examples of an oxidizing gas for use in the above-described oxidation, a mixed gas of hydrogen (H₂) and oxygen (O₂) and a mixed gas of dinitrogen monoxide (N₂O) and nitrogen oxide (NO) may be used in addition to dry oxygen (O₂). It is also possible to use RTA (Rapid Thermal Annealing) in addition to furnace annealing. It is also possible to perform doping of oxide films with nitrogen by a plasma nitriding technology.

The metal impurity 22 is subsequently caused to exist on the gate-insulating films 21, in interfaces on the gate electrode sides of the gate-insulating films, or in proximities of the interfaces. As the metal impurity 22, any of hafnium, aluminum, zirconium, lanthanum, praseodymium, yttrium, titanium, tantalum, and tungsten can be used. Using a film-forming process such as an organic metal chemical vapor deposition (MOCVD) process, an atomic layer deposition (ALD) process or a physical vapor deposition (PVD) process, the metal impurity 22 can be caused to exist directly on the gate-insulating films 21. As an alternative, polysilicon is formed as gate electrodes, and hafnium (Hf) is then introduced by ion implantation.

Upon causing hafnium (Hf) to exist as the metal impurity 22 by the ALD process, for example, very little hafnium (Hf) can be caused exist on the gate-insulating films 21 by conducting cyclic treatments in the order of nitrogen (N₂) feeding, chemical adsorption of hafnium tetrachloride (HfCl₄), nitrogen (N₂) feeding, adsorption of water (H₂O) and nitrogen (N₂) feeding. The metal impurity 22 may be formed, for example, as several layers of hafnium atoms on the gate-insulating films 21.

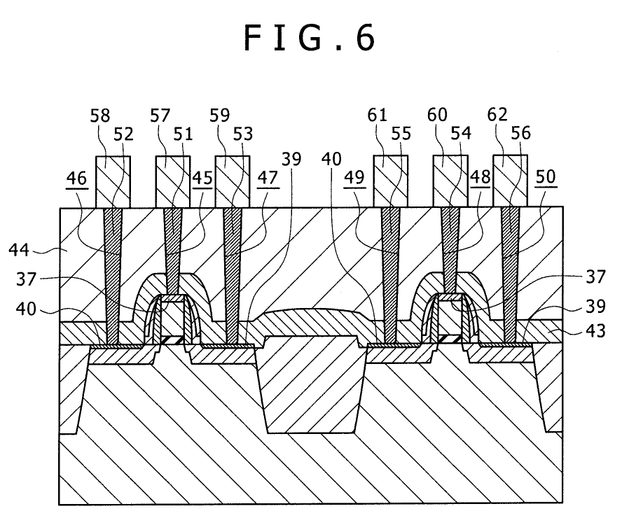

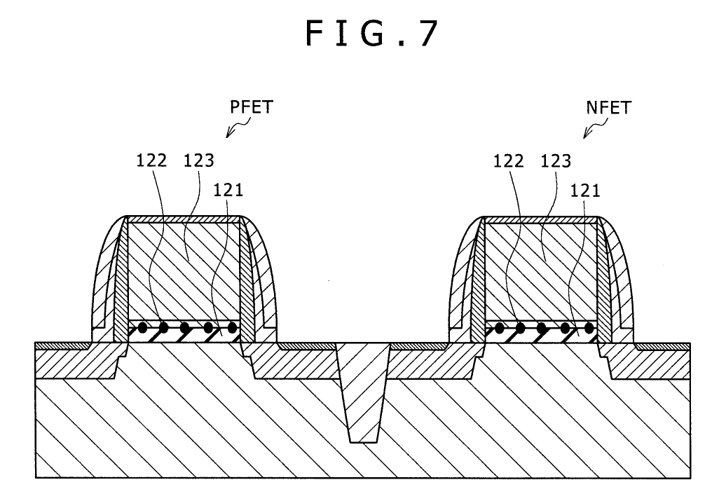

It is to be noted that the illustration of the metal impurity 22 is omitted in FIGS. 5 and 6 to be described subsequently herein.

Upon introducing hafnium (Hf) by ion implantation, on the other hand, polysilicon films are caused to deposit to 100 nm or so, and the polysilicon films are then treated with Hf ions under conditions of 50 keV to 100 kev and 1×10¹⁴ atoms/cm² or so. At this time, the average range of hafnium ions is set around the bottom of polysilicon, in other words, at a location where hafnium is desired to be introduced.

On the gate insulating films 21 subjected to the above-described introduction treatment of the metal impurity 22 (see FIG. 4), electrode-forming films 75 are then formed to form gate electrodes. These electrode-forming films 75 are formed, for example, of polysilicon. As an illustrative process for the formation of the electrode-forming films 75, monosilane (SiH₄) is used as a feed gas, the deposition temperature is set at 580° C. to 620° C., and by a reduced-pressure CVD process, polysilicon is formed as deposits to a thickness of 100 nm to 150 nm.

Next, boron (B) is introduced into the electrode-forming film 75 at the gate electrode region for NFET, and/or phosphorus (P) is introduced into the electrode-forming film 75 at the gate electrode region for PFET. As conditions for the introduction, it is sufficient to set such that the impurity (impurities) does not reach the gate-insulating film(s) 21. Upon introduction of boron (B), for example, boron difluoride ions (BF₂⁺) are used as an impurity, and the implantation energy and dose may be set at 5 keV and 5×10¹⁵ atoms/cm². Upon introduction of phosphorus ions (P⁺), on the other hand, the implantation energy and dose may be set at 5 keV and 5×10¹⁵ atoms/cm².

Subsequently, hard mask layers 76 are formed on the electrode-forming films 75. These hard mask layers 76 are formed, for example, of silicon nitride films, and are formed, for example, to a thickness of 50 nm to 100 nm or so, for example, by a reduced-pressure chemical vapor deposition (LP-CVD) process.

After conducting the formation of a resist film by resist coating and the patterning of the resist film by a lithographic technology, the hard mask layers 76 and electrode-forming films 75 are then subjected to anisotropic etching through the patterned resist film (not shown) as masks to form the gate electrodes (23) (23N, 23P).

As illustrated in FIG. 5, the offset spacers 24, 25 are formed on the side walls of the respective gate electrodes 23 and hard mask layers 76. These offset spacers 24, 25 can be formed, for example, by depositing silicon nitride (Si₃N₄) films in accordance with LP-CVD, for example, to a thickness of 5 nm to 15 nm or so such that the respective hard mask layers 76 and gate electrodes 23 are covered, and then conducting anisotropic etching to leave the silicon nitride films of the side walls of the respective gate electrodes 23 and hard mask layers 76.

After forming an ion implantation mask (not shown), for example, with a resist such that the ion implantation mask covers the element-forming region 13 for NFET, the P-type LDD regions 26, 27 are formed in the element-forming region 12 for PFET. These P-type LDD regions 26, 27 can be formed, for example, by performing ion implantation of boron difluoride ions (BF₂⁺) to the element-forming region 12 at a dose of 5×10¹⁴ atoms/cm² to 2×10¹⁵ atoms/cm² under an implantation energy of 3 keV to 5 keV.

Subsequently, the ion implantation mask is removed.

After forming an ion implantation mask (not shown), for example, with a resist such that the ion implantation mask covers the element-forming region 12 for PFET, the N-type LDD regions 28, 29 are formed in the element-forming region 13 for NFET. These N-type LDD regions 28, 29 can be formed, for example, by performing ion implantation of arsenic ions (As⁺) to the element-forming region 13 at a dose of 5×10¹⁴ atoms/cm² to 2×10¹⁵ atoms/cm² under an implantation energy of 5 keV to 10 kev.

Subsequently, the ion implantation mask is removed.

Either the P-type LDD regions 26, 27 or the N-type LDD regions 28, 29 may be formed before the other LDD regions.

To inhibit the short channel effect, so-called “halo” implantation is often performed concurrently with the formation of each LDD. For example, the substrate surface is divided into four areas, and from directions of 45 degrees (deg) relative to the substrate surface, boron ions (B⁺) are obliquely ion-implanted into NFET at an implantation energy of 12 keV and 3×10¹³ atoms/cm², and As ions (As⁺) are obliquely ion-implanted into PFET at an implantation energy of 70 keV and 2×10¹³ atoms/cm².

The side walls 31 are next formed on the side walls of the gate electrode 23N and hard mask layer 76 via the offset spacers 24. At the same time, the side walls 32 are formed on the side walls of the gate electrode 23P and hard mask layer 76 via the offset spacers 25. The side walls 31, 32 can be formed by depositing silicon nitride (Si₃N₄), for example, in accordance with plasma CVD to a thickness of 50 nm to 70 nm such that they cover the hard mask layers 76, offset spacers 24, 25 and the like, depositing silicon oxide (SiO₂) to a thickness of 50 nm to 70 nm in accordance with plasma CVD, and then applying anisotropic etching to the silicon oxide film and silicon nitride film.

During the etching, the hard mask layers 76 on the gate electrodes 23N, 23P are also etched together.

As a result, the gate electrodes 23N, 23P are exposed at the top surfaces thereof. FIG. 5 illustrates conditions before the removal of the hard mask layers 76.

After forming an ion implantation mask (not shown), for example, with a resist such that the ion implantation mask covers the element-forming region 13 for NFET, the P-type source-drain regions 33, 34 are formed in the element-forming region 12 for PFET. These P-type LDD regions 33, 34 can be formed, for example, by performing ion implantation of boron difluoride ions (BF₂⁺) to the element-forming region 12 at a dose of 5×10¹⁴ atoms/cm² to 2×10¹⁵ atoms/cm² under an implantation energy of 5 keV to 10 keV.

Subsequently, the ion implantation mask is removed.

After forming an ion implantation mask (not shown), for example, with a resist such that the ion implantation mask covers the element-forming region 12 for PFET, the N-type source-drain regions 35, 36 are formed in the element-forming region 13 for NFET. These N-type source-drain regions 35, 36 can be formed, for example, by performing ion implantation of arsenic ions (As⁺) to the element-forming region 13 at a dose of 1×10¹⁵ atoms/cm² to 2×10¹⁵ atoms/cm² under an implantation energy of 40 keV to 50 keV.

Subsequently, the ion implantation mask is removed.

As the boron (B) in the gate electrode 23P for NFET is more susceptible to activation than As at this time, the semiconductivity type is not reversed unless As is implanted in a large amount. Further, the phosphorus (P) in the gate electrode 23N for PFET is far more susceptible to activation than boron (B), and therefore, the semiconductivity type is not reversed unless boron (B) is implanted in a large amount.

Either the P-type source-drain regions 33, 34 or the N-type source-drain regions 35, 36 may be formed before the other source-drain regions.

Activation of the impurities are then conducted by RTA (Rapid Thermal Annealing) under conditions of 1,000° C. and 5 seconds to construct the first transistor 2 consisting of the P-type insulated gate field effect transistor (PFET) and the second transistor 3 consisting of the N-type insulated gate field effect transistor (NFET).

A metal film is next formed to conduct silicidation. As an example of this metal film, a cobalt (Co) film is used. The cobalt film is formed, for example, by depositing cobalt (Co) to a thickness of 6 nm to 8 nm by sputtering.

Subsequently, RTA is performed under conditions of 500° C. to 600° C. and 30 seconds to conduct silicidation (CoSi) on the silicon only. Unreacted cobalt (Co) on the oxide film is then removed by wet etching. In this wet etching, a so-called sulfuric acid hydrogen peroxide mixture composed of sulfuric acid (H₂SO₄) and hydrogen peroxide solution is used.

RTA is subsequently conducted at 650° C. to 850° C. for 30 seconds to produce low-resistance CoSi₂ on the gate electrode 23N, source-drain regions 33, 34, gate electrode 23P, and source-drain regions 35, 36, so that the low-resistance silicide layers 37, 38, 39, 40, 41, 42 are formed.

Instead of cobalt silicide, it is also possible to use nickel silicide (NiSi) obtained by depositing nickel (Ni) or nickel platinum (NiPt) and subjecting it to a silicidation reaction.

As depicted in FIG. 6, an etching stopper layer 43 is next formed over the entire surface on the side that the silicide layers 37 to 42 are formed. This etching stopper layer 43 is formed, for example, of a silicon nitride film.

Further, an interlayer insulating film 44 is formed. After a silicon oxide (SiO₂) film is deposited, for example, to a thickness of 300 nm to 1,000 nm or so, for example, by CVD, the surface of the interlayer insulating film 44 is planarized by chemical mechanical polish (CMP). This polish is conducted until the thickness of the interlayer insulating film 44 on the gate electrodes 23N, 23P becomes 100 nm to 800 nm.

By lithographic technology and etching technology in related art, interconnecting holes 45 to 50 are formed in the interlayer insulating film 44 such that they extend to the respective silicide layers 37 to 42. As the etching stopper layer 43 has been formed, the etching can be stopped at the silicon nitride above the respective silicide layers 37 to 42 by setting etching conditions for the formation of the interconnecting holes 45 to 50 such that a selection ratio to silicon nitride can be assured.

As a consequence, any excessive etching to the silicide layers 37 to 42 can be avoided so that the implantation of compensation ions for the reduction of a junction leakage can be reduced.

The silicon nitride is then removed only as much as the thickness of the etching stopper 43 to form the interconnecting holes 45 to 50.

On the inner walls of the respective interconnecting holes 45 to 50, films which are composed, for example, of titanium (Ti) are formed as adhesion layers (not shown), and films which are composed, for example, of titanium nitride (TiN) are then formed as barrier metal layers (not shown).

Subsequently, tungsten (W) is deposited, for example, by CVD such that the respective interconnecting holes 45 to 50 are buried, and any surplus tungsten (W), barrier metal layers and adhesion layers on the interlayer insulating film 44 are removed, for example, by CMP.

As a result, plugs 51 to 56 composed of tungsten (W) are formed in the respective interconnecting holes 45 to 50 via the adhesion layers and barrier metal layers.

For the formation of the titanium (Ti) films as the adhesion layers and the titanium nitride (TiN) films as the barrier metal layers, a process such as sputtering making use of IMP (ion metal plasma) may be used in place of CVD, and overall etch-back may be used in place of CMP.

Subsequently, interconnecting conductors 57 to 62 are formed in contact with the respective plugs 51 to 56. This formation of the interconnecting conductors is conducted by an interconnecting conductor forming technology in related art. The interconnecting conductors 57 to 62 are formed with an interconnecting conductor material useful in semiconductor devices in related art such as, for example, aluminum, copper, a high melting-point metal, a metal compound like a metal silicide.

A CMOS circuit is formed as described above. The conductor layer permits multilayer interconnection. Depending on the application purpose, the conductor layer may be constructed in the form of such multilayer interconnection.

The conductor layer may also be formed with conductors of copper or the like while using a trench wiring structure (for example, a damascene structure, dual damascene structure, or the like).

According to the above-described fabrication process, no gate depletion layer is formed and a higher gate capacitance can be obtained, because the gate electrode 23N composed of N-type polysilicon is formed in the first transistor 2 as PFET and the gate electrode 23P composed of P-type polysilicon is formed in the second transistor 3 as NFET. The term “higher gate capacitance” as used herein does not mean to increase the parasitic capacitance by increasing the gate capacitance beyond necessity. It means to obtain a gate capacitance which should be inherently available from miniaturization if no impairment took place due to gate depletion.

Further, the gate-insulating films 22 are provided on the sides of the gate electrodes 23 with the metal impurity 22 such as hafnium or aluminum. It is, therefore, possible to change the effective work function, for example, by 0.1 V to 0.3 V or so.

Because a high threshold voltage can be achieved, GIDL (gate induced drain leakage) can be reduced by inhibiting a mobility reduction due to ionized impurity scattering and achieving electric field relaxation.

As the effective work function can be controlled while inhibiting gate depletion, the present invention has the advantages that leakage can be reduced and the mobility can be improved.

It should be understood by those skilled in the art that various modifications, combinations, sub-combinations and alternations may occur depending on design requirements and other factors insofar as they are within the scope of the appended claims or the equivalent thereof.

What is claimed is:

1. A semiconductor device comprising:
an insulated gate field effect transistor of a first conductivity type as a first transistor, said first transistor having a gate insulating film and a gate electrode; and
an insulated gate field effect transistor of a second conductivity type opposite to said first conductivity type as a second transistor, said second transistor having a gate insulating film and a gate electrode; wherein
said gate insulating film of said first transistor and said gate insulating film of said second transistor are provided on sides of said gate electrodes with a metal impurity, respectively, and
said gate electrode of said first transistor includes polysilicon of said second conductivity type, or said gate electrode of said second transistor includes polysilicon of said first conductivity type, or said gate electrode of said first transistor includes polysilicon of said second conductivity type and said gate electrode of said second transistor includes polysilicon of said first conductivity type.

2. The semiconductor device according to claim 1, wherein said metal impurity is selected from the group consisting of hafnium, aluminum, zirconium, lanthanum, praseodymium, yttrium, titanium, tantalum, and tungsten.

3. The semiconductor device according to claim 1, wherein
said first transistor is a P-type field effect transistor,
said second transistor is an N-type field effect transistor, and
said gate electrode of said first transistor includes N-type polysilicon, or said gate electrode of said second transistor includes P-type polysilicon, or said gate electrode of said first transistor includes N-type polysilicon and said gate electrode of said second transistor includes P-type polysilicon.

4. The semiconductor device according to claim 3, wherein
said first transistor includes fluorine introduced in a channel thereof, and
said second transistor includes nitrogen introduced in a channel thereof.

5. A process for the fabrication of a semiconductor device, said process including formation of a P-type gate insulated field effect transistor as a first transistor and an N-type gate insulated field effect transistor as a second transistor, comprising the steps of:
forming a gate-insulating film on a semiconductor substrate;
depositing a metal impurity on said gate-insulating film;
forming gate electrodes for said first transistor and second transistor, respectively, on said gate insulating film with said metal impurity deposited thereon;
forming source and drain regions in said semiconductor substrates at locations on opposite sides of said respective gate electrodes; and
conducting at least one of introduction of an N-type impurity into said gate electrode for said first transistor and introduction of a P-type impurity into said gate electrode for said second transistor.

6. The process according to claim 5, comprising a step of implanting metal ions into said gate insulating film in place of the step of depositing said metal impurity on said gate-insulating film.

7. The process according to claim 5, further comprising, prior to the formation of said gate insulating film, the following steps of:
introducing fluorine into a region in said semiconductor substrate, where a channel for said first transistor is to be formed; and
introducing nitrogen into a region in said semiconductor substrate, where a channel for said second transistor is to be formed.
